(19) United States
(12) Patent Application Publication
(10) Pub. No.: US 2003/0218872 A1
(43) Pub. Date: Nov. 27, 2003

(54) Superconducting magnetic shield

(76) Inventors: Keiji Tsukada, Kashiwa (JP); Kuniomi Ogata, Hachioji (JP); Daisuke Suzuki, Kodaira (JP); Akihiko Kandori, Kokubunji (JP); Koichi Yokosawa, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/442,956

(22) Filed: May 22, 2003

(30) Foreign Application Priority Data
May 23, 2002 (JP) 2002-148516

(51) Int. Cl. H05K 9/00

(52) U.S. Cl. 361/816

(57) ABSTRACT

The invention provides the configuration which gives an open feeling of a small-sized magnetic shield and precision measurement equipment which uses the magnetic shield and the S/N ratio of which is high. A magnetic shield in which openings at both ends of the cylindrical magnetic shield made of ferromagnetic material and having a surface parallel to the axial direction of the superconducting ring are arranged between superconducting rings which form a pair of closed loops and build ringed superconducting wire inside opposite to a plane of the superconducting ring is used for biomagnetic measurement equipment. A direction of a plane of a detection coil of the biomagnetic measurement equipment is arranged in parallel with the axis of the superconducting ring. As a result, the magnetic shield which gives an open feeling, which is light and small-sized can be realized.

### BACKGROUND OF THE INVENTION

1. Field of the Invention

The present invention relates to a magnetic shield for removing the effect of outer magnetic field noise upon a survey instrument, physical and chemical equipment and a magnetic field measuring instrument respectively using various magnetic measurement or using an electron beam.

2. Description of the Related Art

Heretofore, a magnetic shield for shielding from an external magnetic field is used for a biomagnetism measuring instrument for measuring a feeble magnetic field generated from an organism in addition to an electron microscope and an electron beam lithography respectively using an electron beam. For the configuration of a magnetically shielded room, three types have been roughly reported. For first structure, there is a magnetically shielded room that surrounds by ferromagnetic material such as a permalloy and ferrite the permeability of which is high and that forms magnetically shielded space. For the structure, the magnetically shielded space is defined by tightening plates made of a permalloy which is an Fe—Ni alloy including Ni having high permeability by 35 to 80% without clearance by bolts to be a frame of box structure made of aluminum and stainless steel. In case a permalloy laid on a wall is a first layer, some layers are piled to further enhance a rate of magnetic shielding. Normally, a second layer made of a permalloy is provided further apart by 10 mm or more on a first layer 2 mm thick in which two permalloys each of which is 1 mm thick are piled. Similarly, the rate of shielding is enhanced by providing a third layer and a fourth layer. Generally, a wall made of aluminum and having the thickness of approximately 1 to 10 mm so that not only magnetic shielding but the shielding of a radio wave are enabled is provided between layers made of a permalloy. However, in the magnetic shield made of a permalloy, multiple parts are required and thermal annealing treatment after working is required. Therefore, magnetic shield structure using magnetic shielding sheets having laminated structure in which a soft magnetic amorphous alloy having high permeability and having the thickness of 100 μm or less is overlapped with a polymeric film or foil of conductive copper or aluminum in place of a permalloy is disclosed in Japanese Patent Application Laid-Open No. 2000-77890. For the material, a soft magnetic amorphous alloy which is made of Fe—B—Si—Cu, Co—Fe—Si—B, Co—Fe—Ni—Si—B or Fe—Cu—Nb—Si—B, the size of the grain boundary of which is 100 nm or less and having hyperfine crystal structure is used, and a thin film of the soft magnetic amorphous alloy is bonded to a polymeric sheet. Hereby, the magnetic shield can be manufactured by only bonding a flexible magnetic shielding sheet having high permeability to magnetic shield structure. Besides, not structure completely surrounding space such as a magnetically shielded room but cylindrical magnetic shield structure both ends of which are open is reported on D. Suzuki, et. al., Jpn. J. Appl. Phys. Vol. 40 (2001) pp. L1026 to 1028.

For second structure, an active coil-type magnetic shield in which an outer magnetic field is measured by a magnetic sensor such as a flux gate and a superconducting quantum interference device (SQUID) and a magnetic field in a reverse direction is applied using a coil so that the measured outer magnetic field is negated is reported. Besides, there is a magnetically shielded room in which an active shield formed by a large-sized Helmholtz coil is combined outside the magnetically shielded room using this and a permalloy. Hereby, the number of laminated permalloys is reduced and simple structure is acquired.

For third structure, the complete diamagnetic characteristic of a superconductor is used so that an outer magnetic field cannot enter. Particularly, as a high-temperature superconductor can be cooled by liquid nitrogen, it is often used for a magnetic shield, compared with a low-temperature superconductor. A superconductor made of YBa₂Cu₃O_{y}, Ba₂Sr₂CaCu₂O_{y} or Ba₂Sr₂Ca₂Cu₃O_{y} is used for high-temperature superconductor and a superconductor made of NbTi or Nb₃Sn is used for low-temperature superconductor. For the form, a plate and wire may be used. For the structure of, a magnetic shield using a superconductor, a cylindrical magnetic shield both ends of which are open or the only either side of which is open is reported. In Japanese Patent Application Laid-Open No. 8-102416, a magnet for MRI provided with a magnetic shield using a superconducting coil is disclosed, however, as a shielding coil for preventing a magnetic field made by the coil which is the magnet for MRI from leaking outside is used, the object is different. The coil can make current from an external current source flow, current is made to flow on the coil to make a magnetic field applied for MRI and current is made to flow on the shielding coil so that the magnetic field is canceled. Therefore, the current source is required for the shielding coil. Besides, in Japanese Patent Application Laid-Open No. 11-283823, a shielding coil for MRI is also disclosed, however, these coils are similarly required to make shielding current from the external current source flow.

In a magnetically shielded room having high permeability and made of ferromagnetic material, the whole is required to be surrounded. Further, to enhance the rate of shielding, laminated space is required to be formed. Therefore, as the capacity of the magnetically shielded room is large and the magnetically shielded room is heavy, a large installation location is required. Further, for an electron microscope and an electron beam lithography installed in a clean room which is a location for manufacturing a semiconductor device, as the magnetically shielded room makes closed space, an air conditioning system is also further required in the magnetically shielded room, the scale of the magnetically shielded room is enlarged and the cost is also increased. In the meantime, to improve closeness, there is also a cylindrical shield both ends of which are open, however, as an outer magnetic field leaks from the open end, approximately the double or more length of the diameter of an opening is required.

In an active shield, the lightening and the opening of a magnetically shielded room are realized. However, a feedback system in which current is made to flow into a coil so that an outer magnetic field is negated after the outer magnetic field is measured cannot completely correspond to any frequency of the outer magnetic field and a phase lag is caused in a shielding magnetic field by a circuit including the coil. Particularly, in active shielding combined with a simple magnetically shielded room, a phase lag is caused not only due to a circuit but due to a ferromagnetic body. A range of magnetic field strength in which an outer magnetic field can be negated is determined depending upon a position in which a magnetometric sensor for measuring an outer magnetic field is installed and the resolution of the magnetic field. Therefore, in the active shielding, magnetism made by the active shield itself may be noise that cannot be ignored due to the variation of a phase between the magnetometric sensor for measuring an outer magnetic field and a shielding magnetic field.

In case a superconductor is used for a magnetic shield, space for magnetic shielding is required to be formed as continuous structure. Therefore, it is difficult to form large structure by high-temperature superconductive plates because of the limit in size of a heating furnace for burning in a manufacturing process and because integrated structure completely surrounding space cannot be manufactured. Then, cylindrical structure both ends of which are open or only one end of which is open is reported. However, it is difficult to make a mechanism which can be freely opened such as a door except the openings. As the area of a superconductor is large, much power is required for a cryocooler as a cooling system, and a superconductor and a cooling system are high-priced. A coil in which superconducting wire is wound manifold is reported in addition to bulky material, however, as shielding space is also used inside the coil, a continuous coil having fixed or more length is required. Therefore, there is a problem that though both ends are open, an opening except them cannot be freely formed. Besides, for a shielding coil for MRI, an external current source for making shielding current to flow is required.

### SUMMARY OF THE INVENTION

In the invention, outer magnetism is shielded utilizing complete diamagnetism which is a characteristic of superconductivity by using a superconductor forming a closed loop differently from a superconducting coil connected to an external current source. For the configuration of a magnetic shield, a pair of superconducting rings arranged opposite in a direction of the axis of the superconducting rings forming a closed loop are used. The superconducting ring includes a type of a closed loop in which both ends of a coil acquired by winding superconducting wire are superconductively connected and a type in which bulky superconductive material is formed in a ring. Hereby, the problems of closeness and a large location required for installation which are the problems of the conventional type magnetically shielded room using ferromagnetic material having high permeability are improved. Further, the uniformity of a magnetic field in magnetically shielded space is enhanced by increasing the number of independent pairs of superconducting rings forming a closed loop. Besides, the uniformity of a magnetic field is further enhanced by increasing the diameter of plural pairs of superconducting rings toward the center of the space.

For the configuration of the magnetic shield, configuration that two pairs of superconducting rings each pair of which is arranged opposite in a direction of the axis of the superconducting rings forming a closed loop are provided, respective axes are perpendicular and the center of the axes is coincident is adopted. According to the configuration, a magnetic field component parallel to a plane formed by two axes of the superconducting ring can be shielded. Further, a magnetic field component in all directions can be shielded by adopting configuration that three pairs of superconducting rings are provided, respective axes are perpendicular and the center of the axes is coincident.

As the magnetic shield according to the invention has a shorter cylinder, compared with the conventional type cylindrical magnetic shield made of ferromagnetic material, the magnetic shield that gives an open feeling is realized by combining a cylindrical magnetic shield made of ferromagnetic material and having a plane parallel to a direction of the axis of the superconducting ring with a pair of superconducting rings. The limit of operation by a subject or a measuring instrument via openings at both ends of the cylinder is removed and the operation on the side of the cylinder is enabled by providing a door mechanism to the cylindrical magnetic shield made of ferromagnetic material. Such a mechanism can be freely formed by using ferromagnetic material for the material of the cylinder in place of an integrated cylinder made of superconductive material.

For a magnetic shield for biomagnetic measurement equipment, a magnetic shield having configuration that three pairs of superconducting rings are provided, respective axes are perpendicular and the center of the axes is coincident is used. Hereby, as an outer magnetic field in all directions can be shielded, biomagnetic measurement the S/N ratio of which is high is enabled. A pair of superconducting rings are arranged so that a plane of a detection coil in biomagnetic measurement is perpendicular to the axis of the superconducting ring. Hereby, as an outer magnetic field in a direction of the axis can be shielded, a component in the axial direction in biomagnetic measurement can be detected at satisfactory S/N ratio. Besides, the simple configuration which can give a further open feeling can be provided by limiting a measured component and a shielded component. Besides, a magnetic shield-having configuration that openings at both ends of a cylindrical magnetic shield having a plane parallel to the axial direction of superconducting rings and made of ferromagnetic material are arranged opposite to a plane of the superconducting ring between a pair of superconducting rings is used for biomagnetic measurement equipment. In this case, a plane of a detection coil of the biomagnetic measurement equipment is arranged in parallel with the axis of the superconducting ring. Hereby, as a magnetic field component perpendicular to the axis of the superconducting ring can be effectively shielded in the cylindrical and open magnetic shield, measurement the S/N ratio of which is high is enabled by directing the plane of the detection coil in biomagnetic measurement so that the same perpendicular component can be detected. According to this configuration, as the cylinder can be shortened, compared with the conventional type biomagnetic measurement equipment using a cylindrical magnetic shield both ends of which are open, having high permeability and made of ferromagnetic material, an open feeling is enhanced.

For precision measurement equipment using an electron beam such as an electron microscope, a magnetic shield having configuration that two pairs of superconducting rings each pair of which is arranged opposite in the axial direction of the superconducting rings forming a closed loop are provided, respective axes are perpendicular and the center of the axes is coincident is used. Further, a magnetic field component perpendicular to an electron beam and having an effect upon the electron beam can be shielded by arranging the direction of the electron beam and a plane of the superconducting ring in parallel. Hereby, high-precision photography via the microscope is enabled without being influenced by an outer magnetic field. The conventional type magnetic shield causes closeness, however, according to this configuration, an open feeling is enhanced and no independent air conditioning facility is required even if the magnetic shield according to the invention is installed in a clean room for example Besides, for a magnetic shield for an electron microscope, a magnetic shield having configuration that a cylindrical magnetic shield made of ferromagnetic material and having a plane parallel to the axial direction of superconducting rings is arranged between a pair of superconducting rings in a state in which openings at both ends of the magnetic shield are opposite to a plane of the superconducting ring is used. In this case, the magnetic shield is arranged in parallel with the direction of an electron beam from the electron microscope and the axis of the superconducting ring. Hereby, as a magnetic field component perpendicular to the axis of the superconducting ring can be effectively shielded in the cylindrical and open magnetic shield, a magnetic field having an effect upon an electron beam can be shielded. Therefore, high-precision photography via the microscope is enabled without being influenced by an outer magnetic field. The conventional type magnetic shield causes closeness, however, according to this configuration, an open feeling is enhanced and no independent air conditioning facility is required even if the magnetic shield according to the invention is installed in a clean room for example.

### BRIEF DESCRIPTION OF THE DRAWINGS

FIG. 1 is a cross view showing a superconducting magnetic shield equivalent to a first embodiment of the invention;

FIG. 2 shows relationship between shielding magnetic field strength Bs made by a pair of superconducting rings of the superconducting magnetic shield equivalent to the first embodiment of the invention and outer magnetic field strength Be;

FIG. 3 is a cross view showing a superconducting magnetic shield equivalent to a second embodiment of the invention;

FIG. 4 shows relationship between shielding magnetic field strength Bs made by two pairs of superconducting rings of the superconducting magnetic shield equivalent to the second embodiment of the invention and outer magnetic field strength Be;

FIG. 5 is a cross view showing a superconductive magnetic shield equivalent to a third embodiment of the invention;

FIG. 6 shows relationship between shielding magnetic field strength Bs made by a pair of superconducting rings of the superconducting magnetic shield equivalent to the third embodiment of the invention and outer magnetic field strength Be;

FIG. 7 is a cross view showing a superconducting magnetic shield equivalent to a fourth embodiment of the invention;

FIG. 8 is a cross view showing a superconducting magnetic shield equivalent to a fifth embodiment of the invention;

FIG. 9 is a cross view showing a superconducting magnetic shield equivalent to a sixth embodiment of the invention;

FIG. 10 shows the structure of the superconducting ring according to the invention;

FIG. 11 is a cross view showing magneto-cardiographic equipment using a superconducting magnetic field equivalent to a seventh embodiment of the invention;

FIG. 12 is a cross view showing magneto-cardiographic equipment using a superconducting magnetic field equivalent to an eighth embodiment of the invention;

FIG. 13 is a cross view showing magneto-cardiographic equipment using the superconducting magnetic field equivalent to the eighth embodiment of the invention;

FIG. 14 is a cross view showing magneto-cardiographic equipment using a superconducting magnetic field equivalent to a ninth embodiment of the invention;

FIG. 15 is a cross view showing an electron microscope using a superconducting magnetic field equivalent to a tenth embodiment of the invention; and

FIG. 16 is a cross view showing an electron microscope using a superconducting magnetic field equivalent to an eleventh embodiment of the invention.

### DETAILED DESCRIPTION OF THE PREFERRED EMBODIMENTS

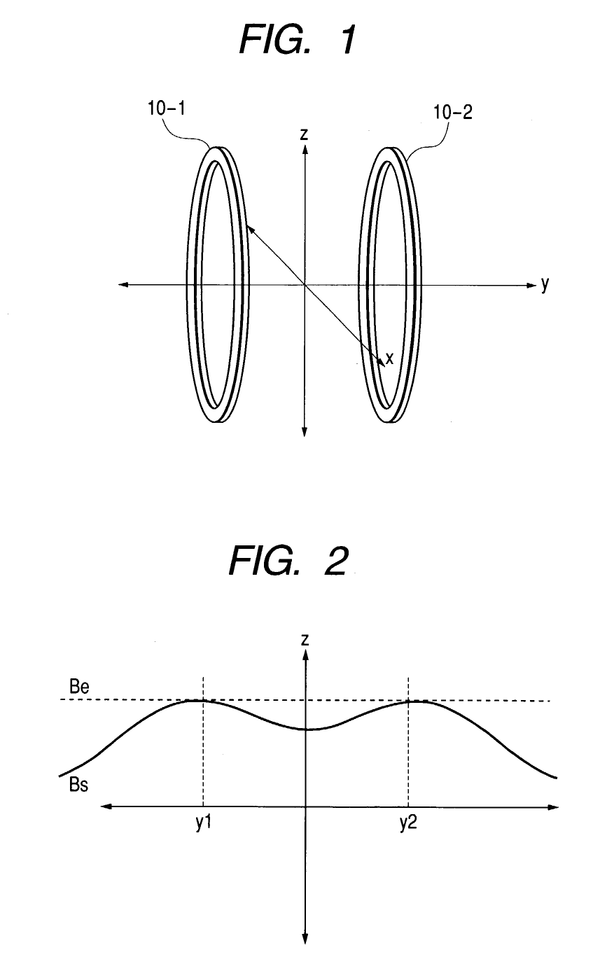

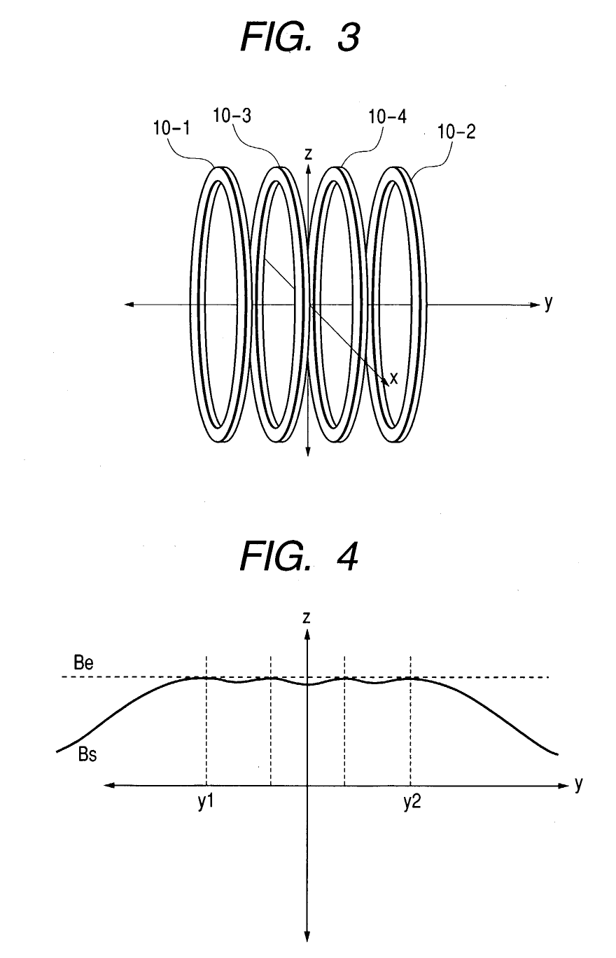

Referring to FIG. 1, a superconducting magnetic shield equivalent to a first embodiment of the invention will be described below. FIG. 1 is a cross view showing a superconducting magnetic shield and FIG. 2 shows a characteristic of magnetic shielding. The superconducting magnetic shield is composed of a pair of superconducting rings 10-1 and 10-2 installed opposite in a direction of the y-axis which is the axis of the superconducting rings as shown in FIG. 1. The y-axis passes the center of the superconducting ring 10-1 and is perpendicular to a plane made by the ring. The x-axis and the z-axis respectively have a value of zero at a point on the y-axis having a value of zero which is a middle point of a pair of superconducting rings 10-1 and 10-2 and the x-, y- and z-axes are mutually perpendicular. Inside the superconducting ring, high-temperature superconducting wire the diameter of which is 2 mm and which is made of Ba₂Sr₂CaCu₂O_{y} is wound like a coil and forms a closed loop in which both ends are superconductively connected. Both ends of the wire are superconductively bonded and form a closed loop by touching both ends of the wire without clearance, inserting the wire into an Ag pipe and crimping it. The superconducting wire is installed in a vacuum housing and is cooled at superconductive transition temperature Tc or lower temperature by a cryocooler to be a superconductive state. The diameter of a coil made by the superconducting wire shall be 1.2 m and distance between a pair of superconducting rings is also set to 1.2 m. Outer magnetic noise which tries to enter the superconducting ring is negated by a plane of the superconducting ring because shielding current flows on the superconducting wire because of the Meissner effect of superconductivity. However, in case only one superconducting ring is provided, a shielding magnetic field attenuates as it is far from the superconducting ring. Therefore, when one more superconducting ring is arranged in the axial direction of the coil, the attenuation of the shielding magnetic field can be reduced. FIG. 2 shows relationship between shielding magnetic field strength Bs generated by a pair of superconducting rings shown in FIG. 1 and outer magnetic field strength Be. For magnetic field strength, Bs and Be in the center of the coil, that is, at a point where x is 0 in the axial direction of the coil, that is, in the direction of the y-axis are shown by a full line and a dotted line. Suppose that locations where the superconducting rings are located are y1 and y2 and the middle point between y1 and y2 is the point where y is 0. Hereby, it is known that in respective coil positions, the strength of an outer magnetic field and that of a shielding magnetic field are completely balanced and shielding functions. The superconducting ring is not only circular but may be arbitrarily shaped if only the ring forms a closed loop.

Referring to FIG. 3, a superconducting magnetic shield equivalent to a second embodiment of the invention will be described below. FIG. 3 is a cross view showing the superconducting magnetic shield and FIG. 4 shows a characteristic of magnetic shielding. As shown in FIG. 2, Bs is smaller than Be in the center of a pair of superconducting rings, that is, at a point where y is 0 in the first embodiment and an outer magnetic field can be attenuated, however, it is known that shielding is not complete. In FIG. 3, to further enhance the uniformity of a shielding magnetic field in space between the superconducting rings 10-1 and 10-2 in the first embodiment, one more pair of superconducting rings 10-3 and 10-4 are further added. The superconducting rings 10-1 and 10-2 are symmetrically arranged with the point where y is 0 in the center and the superconducting rings 10-3 and 10-4 are also symmetrically arranged with the point where y is 0 in the center. From the characteristic of magnetic shielding shown in FIG. 4, it is known that difference in strength between an outer magnetic field and a shielding magnetic field is smaller in the center.

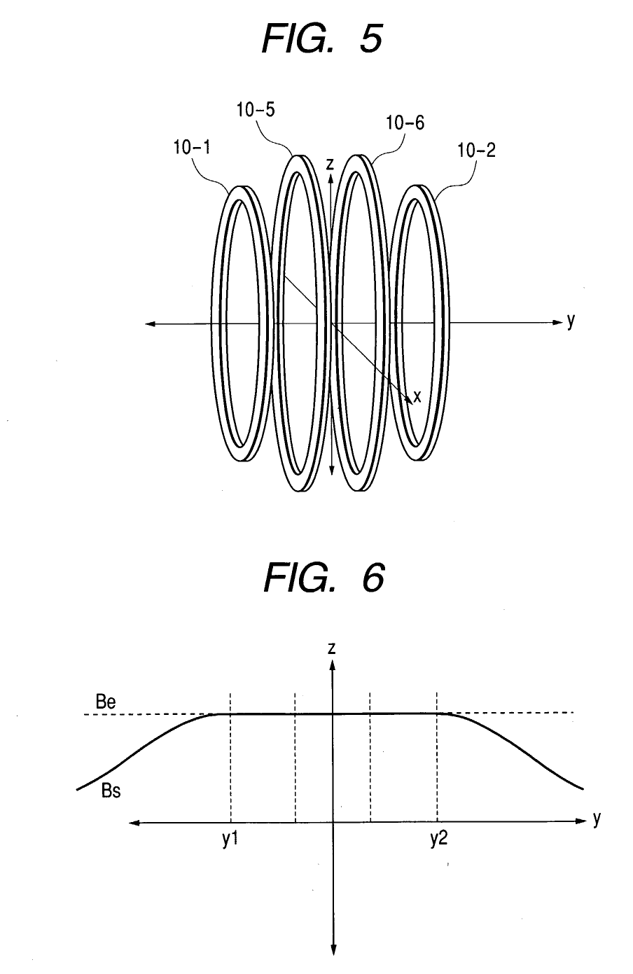

Referring to FIG. 5, a superconducting magnetic shield equivalent to a third embodiment of the invention will be described below. FIG. 5 is a cross view showing the superconducting magnetic shield and FIG. 6 shows a characteristic of magnetic shielding. In FIG. 5, to further enhance the uniformity of the shielding magnetic field in the space between the superconducting rings in the second embodiment, each diameter of a pair of inside superconducting rings 10-5 and 10-6 is made larger than each diameter of outside superconducting rings 10-1 and 10-2 and each diameter of the superconducting rings 10-5 and 10-6 is set to 1.6 m. From the characteristic of magnetic shielding shown in FIG. 6, it is known that difference in strength between an outer magnetic field and the shielding magnetic field in the center is further smaller than the difference in the second embodiment. Each pair of rings are symmetrically arranged with a point where y is 0 in the center.

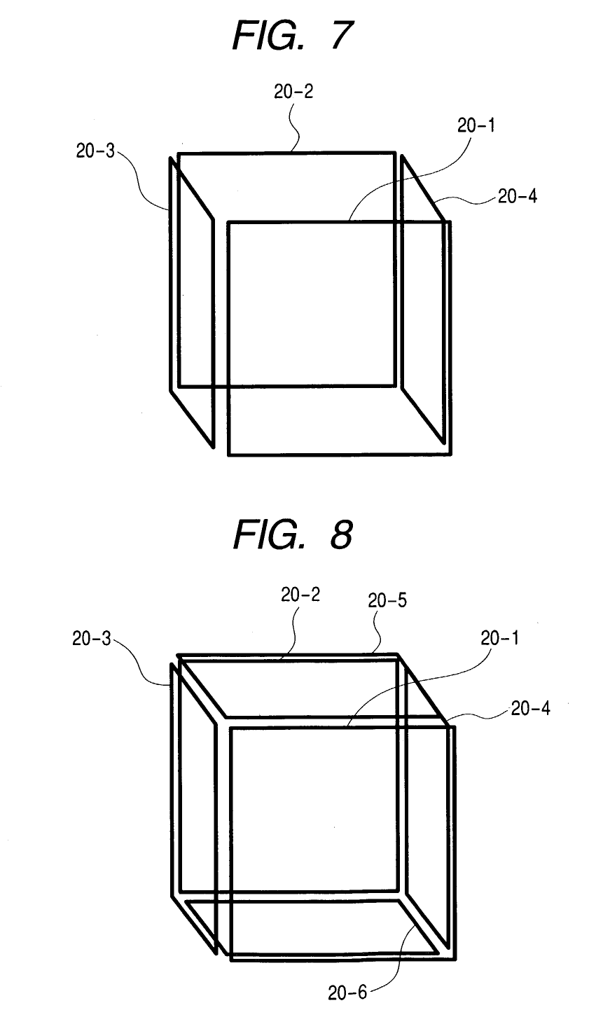

Referring to FIG. 7, a superconducting magnetic shield equivalent to a fourth embodiment of the invention will be described below. In the first to third embodiments, the effect of magnetic shielding is high in the axial direction of the superconducting rings. Therefore, the effect of magnetic shielding is small for a component of a magnetic field in a direction perpendicular to the axis. In the fourth embodiment, a superconducting magnetic shield provided with two pairs of quadrilateral superconducting rings 20-1 and 20-2, 20-3 and 20-4 each axis of which is directed in perpendicular two directions is provided. The shape of each superconducting ring is not circular but quadrilateral. According to this configuration, the magnetic field of a tangential line component in directions of the x-axis and the y-axis can be shielded.

Referring to FIG. 8, a superconducting magnetic shield equivalent to a fifth embodiment of the invention will be described below. In the fifth embodiment, a hexahedral superconducting magnetic shield in which one more pair of superconducting rings 20-5 and 20-6 are added to two perpendicular pairs of quadrilateral superconducting rings 20-1 and 20-2, 20-3 and 20-4 in the fourth embodiment is provided. According to this configuration, a magnetic field component not only in the directions of the x-axis and the y-axis but in all directions can be shielded.

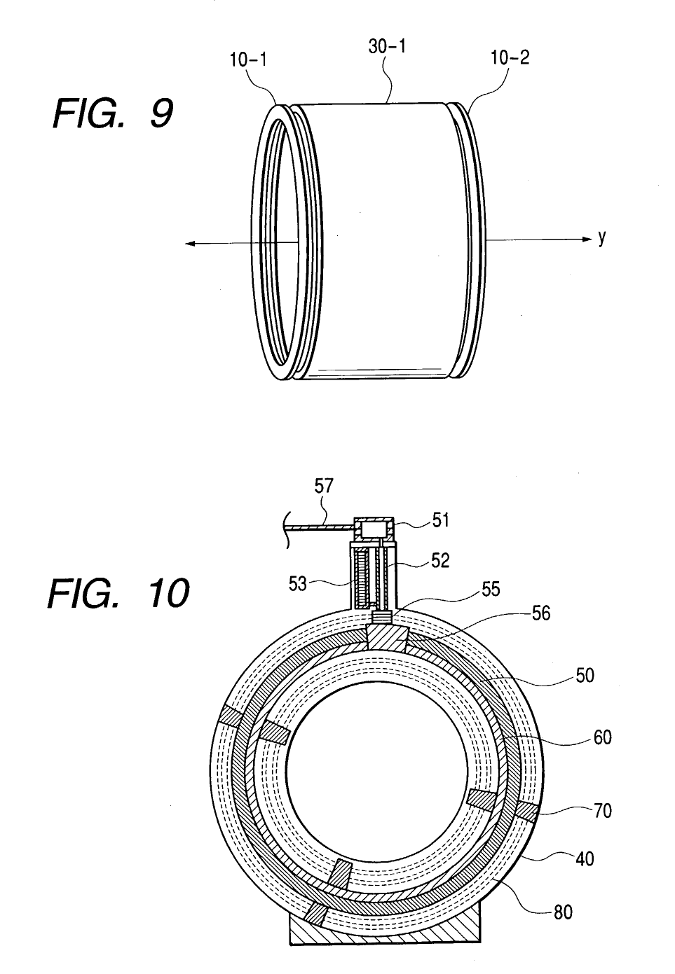

Referring to FIG. 9, a superconducting magnetic shield equivalent to a sixth embodiment of the invention will be described below. In the first embodiment, the effect of magnetic shielding is small for a magnetic field component in a direction perpendicular to the axis of the superconducting ring. Therefore, a magnetic shield 30-1 made of ferromagnetic material is provided between a pair of superconducting rings 10-1 and 10-2. The shape of an opening of the magnetic shield 30-1 made of ferromagnetic material is circular as the shape of each superconducting ring. For the ferromagnetic material, a plate having the thickness of 3 mm in total in which three permalloys 1 mm thick are piled is used. A magnetic shielding sheet having laminated structure in which a soft magnetic amorphous alloy having high permeability and the thickness of 100 μm or less is overlapped with a polymeric film or the foil having conductivity of copper or aluminum can be used in addition to the permalloy. The wall of the magnetic shield 30-1 made of cylindrical ferromagnetic material is made parallel with the axis of the superconducting ring. The diameter of the cylindrical magnetic shield is set to 1.2 m and the length is set to 1 m. Hereby, a magnetic field in a direction perpendicular to the axis which cannot be shielded by only the superconducting rings can be shielded. The length which is required to be larger than the diameter of the opening of the conventional type cylindrical magnetic shield made of ferromagnetic material can be reduced by combining the superconducting rings in the superconducting magnetic shield in which superconductivity and ferromagnetism are combined.

FIG. 10 shows the internal structure of the superconducting ring. Inside the superconducting ring, high-temperature superconducting wire 50 the diameter of which is 2 mm and which is made of Ba₂Sr₂CaCu₂O_{y} is used. Both ends of the wire are superconductively bonded and form a closed loop by touching them without clearance, inserting the wire into an Ag pipe and crimping it. The high-temperature superconducting wire 50 is provided in a vacuum housing, is cooled to be at superconductive transition temperature Tc or lower temperature by a cryocooler and is in a superconductive state. For the cryocooler, a pulse tube refrigerator is used. In addition, any cryocooler that can cool the superconducting wire so that it is at critical temperature or lower temperature such as Gifford Hofmann-type refrigerator can be used. A cold head 55 of the pulse tube refrigerator and the superconducting wire 50 are thermally touched via a connector 56 made of copper. These are thermally shielded from outside air in a superconducting ring housing 40 which is a vacuum housing made of glass fiber reinforced plastic (FRP). To further enhance thermal shielding, super insulation 80 having laminated structure is used. To maintain space between the superconducting ring housing 40 and the superconducting wire 50, a spacer 70 made of FRP is used for a holding member. To accelerate holding to wind the superconducting wire 50, thermal stability and cooling time, a coil support 60 made of copper is provided. The pulse tube refrigerator is composed of a cooling part 58 including a buffer part 51, a pulse tube 52 installed inside the superconducting ring housing 40 which is a vacuum housing, a cold head 55 and a regenerator 53 and a compressor 54 connected from the buffer part 51 to a gas pipe 57.

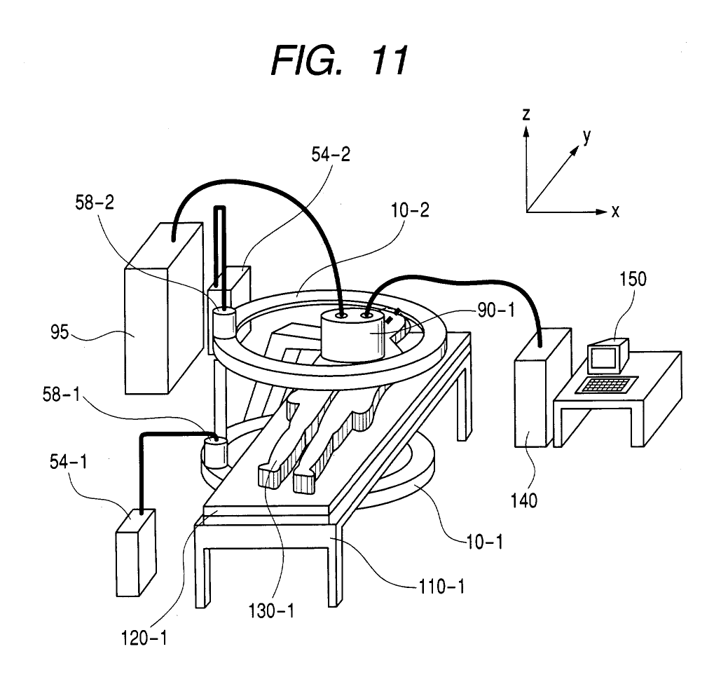

Referring to FIG. 11, magneto-cardiographic equipment equivalent to a seventh embodiment using the superconducting magnetic shield composed of a pair of superconducting rings in the first embodiment of the invention will be described below. The magneto-cardiographic equipment is equipment for measuring a magnetic field generated according to the electrophysiological activity of a heart. The equipment measures a feeble heart magnetic field using a superconducting quantum interference device SQUID and to enhance the efficiency of detection, SQUID is provided with a superconductively connected detection coil. A magnetic field component perpendicular to a plane of the detection coil can be caught. For SQUID, high-temperature superconducting SQUID made of YBa₂Cu₃O_{7-δ} is used. A plane of the coil is arranged so that z component perpendicular to the axis of the superconducting ring of a heart magnetic field is caught. Magnetic shielding is made by a pair of superconducting rings 10-1 and 10-2 and an outer magnetic field in a direction of the z-axis is shielded. As the z component of outer magnetic field noise can be removed by the superconducting rings, the S/N ratio of the z component of a heart magnetic field is satisfactory and the z component can be detected. SQUID and a fluxmeter including the detection coil are built in Dewar vessel 90-1 which is a vacuum vessel. Inside Dewar vessel, liquid nitrogen is held to make the fluxmeter a superconductive state. Evaporated liquid nitrogen is supplemented by a liquid nitrogen feeder 95 at any time. In case not a high-temperature superconductor but a low-temperature superconductor Nb is used for SQUID, liquid helium is used inside Dewar vessel. Dewar vessel is held by a gantry 100-1 and is arranged so that the vessel approaches the chest of a subject 130-1. To optimize the position of the chest for Dewar vessel, a sliding upper plate of a bed 120-1 is provided on the bed 110-1 so that alignment is enabled. The driving and the output of the fluxmeter are made by measuring circuits 140, are input to a data acquisition analyzer 150 as measured data and the result of analysis is displayed.

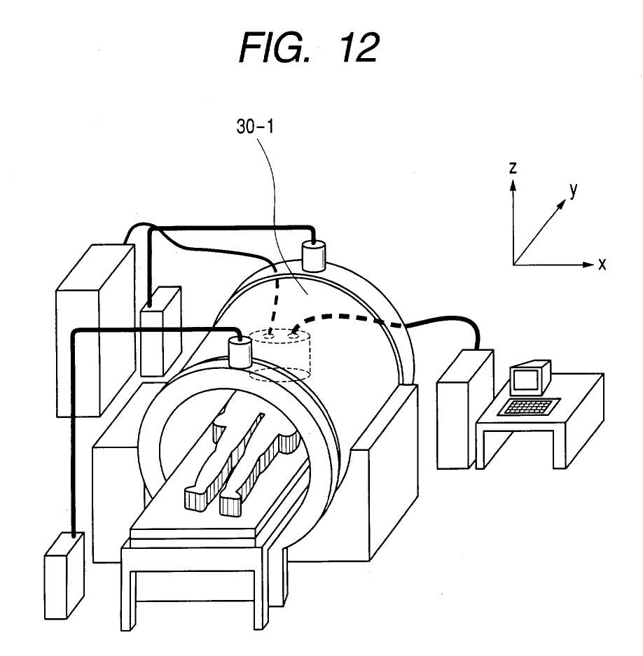

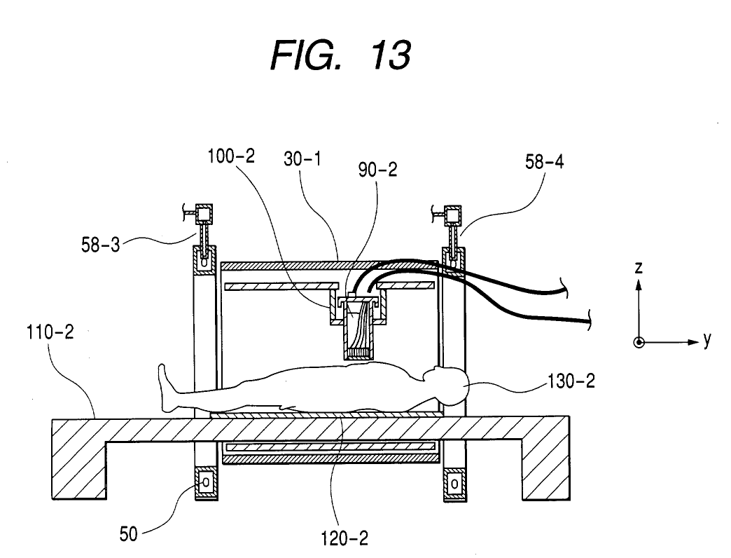

Referring to FIG. 12, magneto-cardiographic equipment equivalent to an eighth embodiment using the superconducting magnetic shield in which a pair of superconducting rings and the magnetic shield made of ferromagnetic material are combined and which is equivalent to the sixth embodiment of the invention will be described below. In this embodiment, a plane of a coil is arranged so that it catches the z component of a heart magnetic field and is directed in a direction of the z-axis in parallel with the axis of the superconducting rings. Magnetic shielding is made by the magnetic shield 30-1 made of ferromagnetic material and a pair of superconducting rings 10-1 and 10-2 and an outer magnetic field in the direction of the z-axis is shielded. As the z component of outer magnetic field noise can be removed by the superconducting rings, the S/N ratio of the z component of a heart magnetic field is satisfactory and the z component can be detected. FIG. 13 shows the internal structure in the sixth embodiment. A subject 130-2 enters the inside of the cylindrical magnetic shield 30-1 made of ferromagnetic material and his/her heart magnetic field is measured. Dewar vessel 90-2 is held over the chest of the subject 130-2 by a gantry 100-2. To optimize the position of the chest for Dewar vessel, a sliding upper plate of a bed 120-2 is provided oh the bed 110-2 so that alignment is enabled. A pair of superconducting rings are arranged at both open ends of the cylindrical magnetic shield made of ferromagnetic material. The length which is required to be the double or more of the diameter of an opening of the conventional type cylindrical magnetic shield made of ferromagnetic material can be greatly reduced by using the superconducting magnetic shield in which a pair of superconducting rings and the magnetic shield made of ferromagnetic material are combined, and an open feeling of the subject and the operability of a measurer can be enhanced. As a superconductor having a large plane is not required in the invention, compared with the magnetic shield disclosed in Japanese published unexamined patent application No. Hei 7-226598 in which ferromagnetic material is combined with the cylindrical bulky superconductor, a cooling system is simplified and further, simple assembly in which the superconducting rings and a ferromagnetic body are separately assembled can be realized.

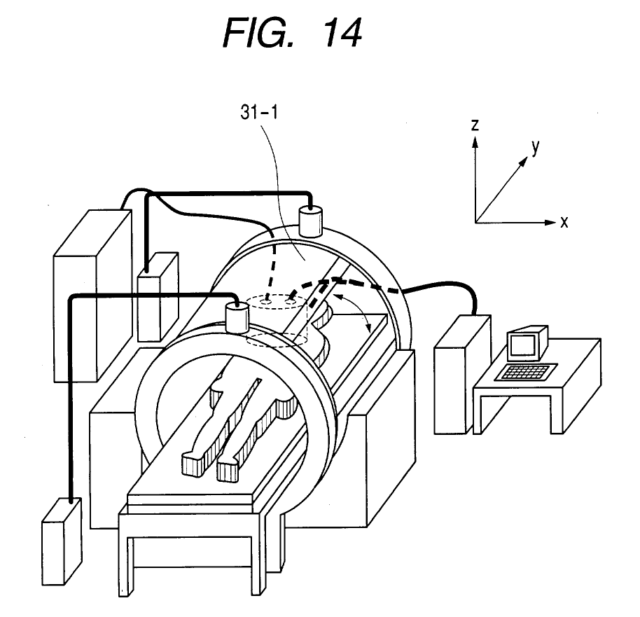

Referring to FIG. 14, magneto-cardiographic equipment equivalent to a ninth embodiment of the invention will be described below. In this embodiment, in place of the magnetic shield 30-1 made of ferromagnetic material of the magneto-cardiographic equipment equivalent to the eighth embodiment, a magnetic shield 31-1 made of ferromagnetic material and provided with a sliding door is provided. The sliding door is provided to the magnetic shield made of ferromagnetic material and a part can be opened/closed. Though a subject can enter or go out of the magnetic shield and a measurer can operate it respectively via only the opening in the eighth embodiment, he/she can enter or go out from the side owing to this structure.

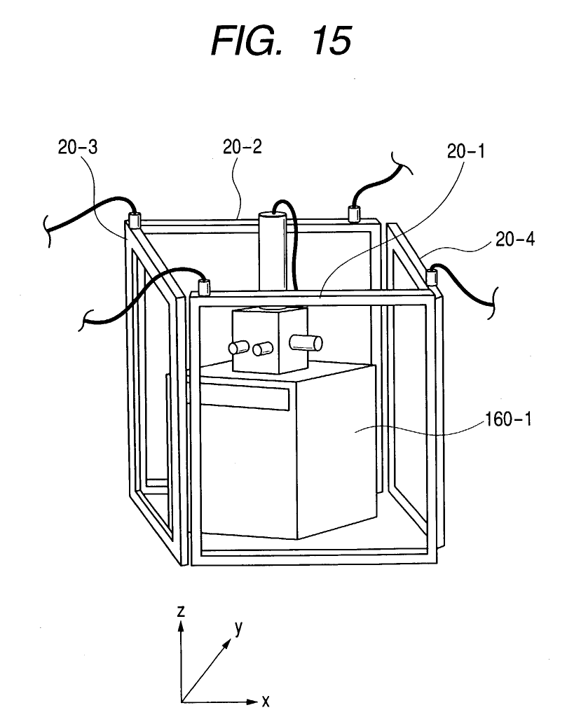

Referring to FIG. 15, a superconducting magnetic shield for an electron microscope equivalent to a tenth embodiment of the invention will be described below. The superconducting magnetic shield provided with two pairs of square superconducting rings 20-1 and 20-2, 20-3 and 20-4 the axis of each coil of which is perpendicular as in the structure used in the fourth embodiment is used for a magnetic shield for an electron microscope. As an electron beam of an electron microscope 160-1 is radiated downward from the upside, a direction of the electron beam and the axial direction of the superconducting ring are vertical.

Hereby, magnetic field components from directions of the x-axis and the y-axis having an effect upon an electron beam can be shielded. Even if an electron microscope is installed in a clean room, only an air conditioning system of the clean room has only to be provided owing to the configuration of the superconducting magnetic shield described above though an air conditioning system is required to be separately provided to a magnetically shielded room in the conventional type magnetically shielded room made of a permalloy and covering the whole space. The superconducting magnetic shield in this embodiment can be used not only for an electron microscope but for an electron beam lithography using an electron beam.

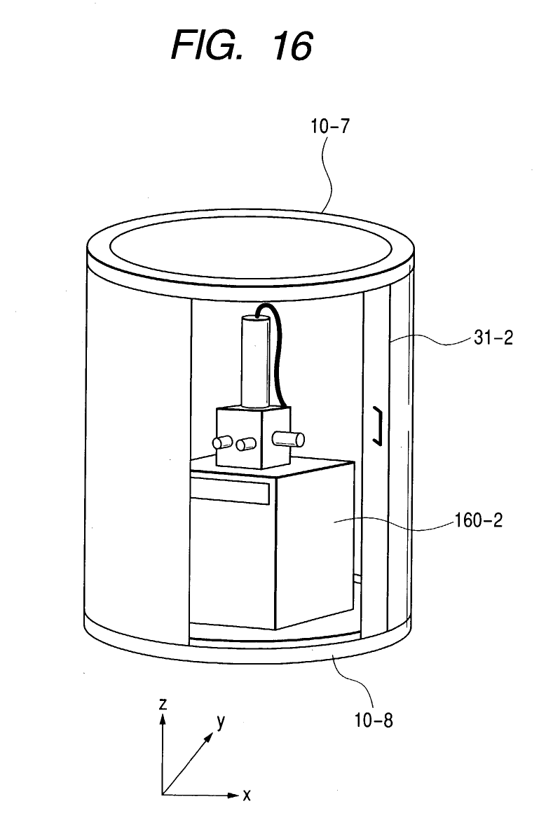

Referring to FIG. 16, a superconducting magnetic shield for an electron microscope equivalent to an eleventh embodiment of the invention will be described below. The superconducting magnetic shield in which a pair of superconducting rings 10-7 and 10-8 and a magnetic shield made of ferromagnetic material and provided with a sliding door 31-2 are combined as in the structure used in the ninth embodiment is used. In FIG. 16, the superconducting magnetic shield is put lengthwise and planes of the superconducting rings are provided above and below. As an electron beam of the electron microscope 160-2 is radiated downward from the upside, a direction of the electron beam and the axial direction of the superconducting ring are parallel. Hereby, magnetic field components in directions of the x-axis and the y-axis which have an effect upon an electron beam can be shielded. The superconducting magnetic shield can be used not only for the electron microscope but for an electron beam lithography using an electron beam. Even if the electronic microscope is installed in a clean room as in the tenth embodiment, structure that does not prevent the flow of air can be supplied by the configuration of the superconducting magnetic shield in this embodiment because conditioned air generally flows downward from the upside in the air conditioning of the clean room though an air conditioning system is required to be separately provided to a magnetically shielded room in the conventional type magnetically shielded room made of a permalloy and covering the whole space.

As described above, as the superconducting magnetic shield according to the invention gives an open feeling and does not require many superconductors, cooling is facilitated. Besides, as shielding current in response to an outer magnetic field can be naturally generated, there is effect that no magnetometric sensor for monitoring is required.

What is claimed is:

1. A superconducting magnetic shield, comprising:
a pair of superconducting rings arranged opposite in the axial direction of the superconducting rings forming a closed loop.

2. A superconducting magnetic shield, comprising:
plural pairs of superconducting rings each pair of which is arranged opposite in the axial direction of the superconducting rings forming a closed loop so that the superconducting rings of each pair are symmetrical with predetermined one point in the center.

3. A superconducting magnetic shield according to claim 2, wherein:
the diameter of each pair of the plural pairs of superconducting rings is made larger toward the predetermined one point; and
the diameter of a pair of superconducting rings is equalized.

4. A superconducting magnetic shield, comprising:
two pairs of superconducting rings each pair of which is arranged opposite in the axial direction of the superconducting rings forming a closed loop, wherein:
respective axes are perpendicular; and
the center of the respective axes is coincident.

5. A superconducting magnetic shield, comprising:
three pairs of superconducting rings each pair of which is arranged opposite in the axial direction of the superconducting rings forming a closed loop, wherein:
respective axes are perpendicular; and
a hexahedron is formed.

6. A superconducting magnetic shield according to claim 1, comprising:
a cylindrical magnetic shield made of ferromagnetic material and having a surface parallel in the axial direction of the superconducting rings between a pair of superconducting rings.

7. A superconducting magnetic shield according to claim 6, comprising:
a sliding door which is provided to a part of the magnetic shield and which can be opened or closed.

8. A method of relatively arranging the superconducting magnetic shield according to claim 5 and biomagnetic measurement equipment, wherein:
the biomagnetic measurement equipment is arranged inside the superconducting magnetic shield.

9. A method of relatively arranging the superconducting magnetic shield according to claim 1 and biomagnetic measurement equipment, wherein:
the biomagnetic measurement equipment is arranged inside the superconducting magnetic shield so that a plane of a detection coil for detecting a magnetic field generated from an object of inspection by the biomagnetic measurement equipment is perpendicular to the central axis of a pair of superconducting rings.

10. A method of relatively arranging the superconducting magnetic shield according to claim 6 and biomagnetic measurement equipment, wherein:
the biomagnetic measurement equipment is arranged inside the superconducting magnetic shield so that a plane of a detection coil for detecting a magnetic field generated from an object of inspection by the biomagnetic measurement equipment is parallel to the axis of the superconducting ring.

11. A method of relatively arranging the superconducting magnetic shield according to claim 6 and precision measurement equipment utilizing an electron beam, wherein:
the precision measurement equipment utilizing an electron beam is arranged inside the superconducting magnetic shield so that a direction of an electron beam radiated from an electron gun of the precision measurement equipment utilizing an electron beam is parallel to the axis of the superconducting ring.

12. A method of relatively arranging, wherein:
the precision measurement equipment utilizing an electron beam is arranged inside the superconducting magnetic shield so that a direction of an electron beam radiated from an electron gun of the precision measurement equipment utilizing an electron beam is perpendicular to the axis of two pairs of superconducting rings of the superconducting magnetic shield according to claim 4.

13. A method of relatively arranging the superconducting magnetic shield according to claim 4 and biomagnetic measurement equipment, wherein:
the biomagnetic measurement equipment is arranged inside the superconducting magnetic shield so that a plane of a detection coil for detecting a magnetic field generated from an object of inspection by the biomagnetic measurement equipment is perpendicular to the central axis of a pair of superconducting rings.

14. A method of relatively arranging the superconducting magnetic shield according to claim 7 and biomagnetic measurement equipment, wherein:
the biomagnetic measurement equipment is arranged inside the superconducting magnetic shield so that a plane of a detection coil for detecting a magnetic field generated from an object of inspection by the biomagnetic measurement equipment is parallel to the axis of the superconducting ring.

15. A method of relatively arranging the superconducting magnetic shield according to claim 7 and precision measurement equipment utilizing an electron beam, wherein:
the precision measurement equipment utilizing an electron beam is arranged inside the superconducting magnetic shield so that a direction of an electron beam radiated from an electron gun of the precision measurement equipment utilizing an electron beam is parallel to the axis of the superconducting ring.
